(19) United States
(12) Patent Application Publication
(10) Pub. No.: US 2026/0262314 A1
(43) Pub. Date: Sep. 3, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Wen Hao Chang, Yunlin County (TW); Jen-Cheng Liu, Hsin-Chu City (TW); Yen-Yu Chen, Kaohsiung City (TW); Tzu-Ming Wang, Tainan City (TW)

(21) Appl. No.: 19/068,453

(22) Filed: Mar. 3, 2025

(51) Int. Cl. H10F 39/00; H10F 39/10; H10F 39/12

(52) U.S. Cl. CPC H10F 39/807; H10F 39/024; H10F 39/026; H10F 39/103; H10F 39/199; H10F 39/8057

(57) ABSTRACT

A semiconductor device includes a semiconductor substrate having a plurality of photodiodes formed therein, a trench isolation grid having a plurality of trench isolation units vertically extending into the substrate from the backside surface thereof to a first level adjacent to or identical to a frontside surface thereof, and a metallic grid having a plurality of metallic units. A trench isolation unit laterally surrounds a photodiode. A metallic unit includes a first portion vertically extending into the trench isolation unit from an upper surface thereof to the first level and laterally surrounded by the trench isolation unit, and a second portion vertically overlaying the first portion and protruding from the upper surface of the trench isolation unit into the first dielectric layer to a second level lower than an upper surface of the first dielectric layer.

### BACKGROUND

Digital cameras and other optical imaging devices employ image sensors. Image sensors convert optical images to digital data that may be represented as digital images. An image sensor includes an array of pixel sensors and supporting logic. The pixel sensors of the array are unit devices for measuring incident light, and the supporting logic facilitates readout of the measurements. One type of image sensor commonly used in optical imaging devices is a back side illumination (BSI) image sensor. BSI image sensor fabrication can be integrated into conventional semiconductor processes for low cost, small size, and high integration. Further, BSI image sensors have low operating voltage, low power consumption, high quantum efficiency, low read-out noise, and allow random access.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 is a cross-sectional view of a semiconductor structure for BSI pixel sensors in accordance with some embodiments.

FIG. 2 is a top view of a part of the semiconductor structure for BSI pixel sensors taken along cutline A-A’ in FIG. 1 in accordance with some embodiments.

FIG. 3 illustrates an implementation and some dimensions of a partial semiconductor structure in accordance with an embodiment.

FIG. 4 illustrates another implementation and some dimensions of a partial semiconductor structure in accordance with another embodiment.

FIG. 5 illustrates another yet implementation and some dimensions of a partial semiconductor structure in accordance with another yet embodiment.

FIG. 6 is a cross-sectional view of a semiconductor structure for a BSI image sensor package in accordance with some embodiments.

FIGS. 7-17 are cross-sectional views of intermediate semiconductor structures that show some example steps for fabricating a semiconductor structure for BSI pixel sensors in accordance with some embodiments.

FIG. 18 is a flow chart showing processes implemented in a method of fabricating the semiconductor structure for BSI pixel sensors as shown in FIG. 1 in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/- 10% or +/- 5%, while in other embodiments, the terms “approximately” and/or “about” can be interpreted as meaning within the normal fabrication tolerances of a given fab manufacturing flow.

Back side illumination (BSI) image sensors include an array of pixel sensors. A semiconductor structure for the BSI image sensors includes an integrated circuit having a semiconductor substrate and photodiodes corresponding to the pixel sensors arranged within the substrate. A back-end-of-line (BEOL) metallization stack of the integrated circuit underlies the semiconductor substrate along a frontside of the semiconductor substrate. Color filters (CFs) and micro lenses (MLs) of the semiconductor structure correspond to the pixel sensors and are stacked in that order over the photodiodes of the corresponding pixel sensors on a backside of the semiconductor substrate.

When a BSI image sensor includes a trench isolation grid in the semiconductor substrate and a metallic grid overlaying the trench isolation grid, optical isolation between neighboring pixel sensors can be improved. The trench isolation grid can be implemented by filling a dielectric material in deep trench isolation (DTI) regions arranged in the semiconductor substrate around and between the photodiodes. The metallic grid can be implemented in a layer overlaying the semiconductor substrate. However, the dielectric material filled in the DTI regions of the trench isolation grid can cause a light leakage among neighboring photodiodes due to relatively high light transmittance of the dielectric material, thereby undesirably causing crosstalk among neighboring photodiodes. Additionally, an alignment shift problem between the trench isolation grid and the metallic grid may occur due to the processes employed to form the metallic grid overlaying the trench isolation grid, thereby undesirably reducing the light reflection of the grids and affecting the light path of the BSI image sensor.

In view of the forgoing, in some embodiments, the present disclosure is directed to a semiconductor structure for BSI image sensors and a method of fabricating the semiconductor structure, in which a metallic grid is self-aligned with a trench isolation grid, fully extends into the trench isolation grid from an upper surface of the trench isolation grid to a first level adjacent to, flush with, or even lower than a frontside surface of a semiconductor substate, and protrudes from the upper surface of the trench isolation grid to a second level. As such, the metallic grid and the trench isolation grid combinedly create a composite metallic grid, thereby advantageously mitigating the alignment shift problem between the metallic grid and the trench isolation grid and the crosstalk problem among neighboring photodiodes.

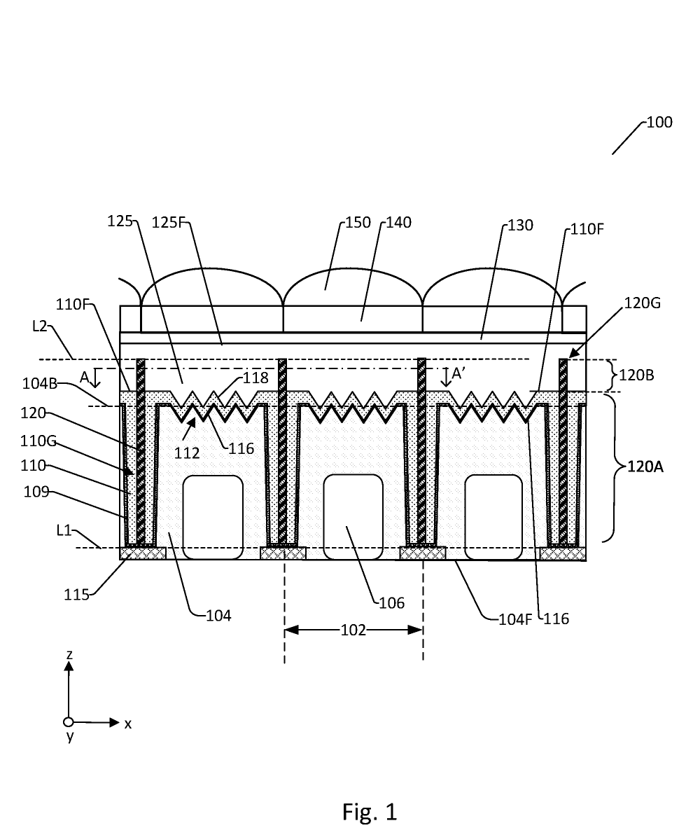

FIG. 1 is a cross-sectional view of a semiconductor structure 100 for BSI pixel sensors 102 in accordance with some embodiments. In some embodiments, the semiconductor structure 100 includes a plurality of BSI pixel sensors 102 that are typically arranged within a pixel sensor array (not shown). In some embodiments, the semiconductor structure 100 includes a semiconductor substrate 104 within which photodiodes 106 corresponding to the pixel sensors 102 are arranged. The photodiodes 106 are arranged in rows and/or columns within the semiconductor substrate 104, and configured to accumulate charge (e.g., electrons) from photons incident on the photodiodes 106 from a backside of the semiconductor substrate 104. The semiconductor substrate 104 may be, for example, a bulk semiconductor substrate, such as a bulk silicon substrate, or a silicon-on-insulator (SOI) substrate. The semiconductor substrate 104 has a frontside surface 104F and a backside surface 104B.

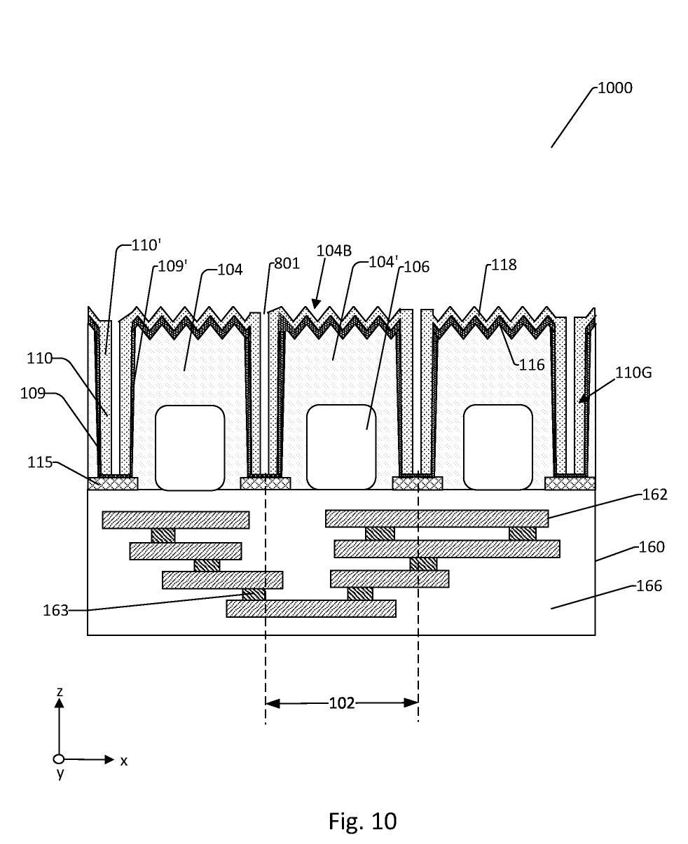

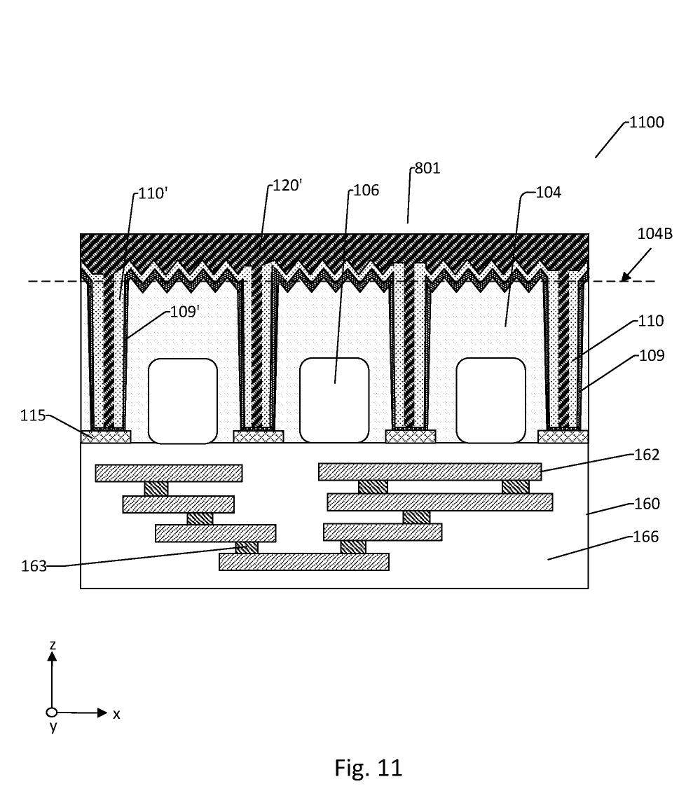

In some embodiments, as shown in FIG. 1, the semiconductor structure 100 for BSI pixel sensors 102 further includes a first dielectric layer 125 arranged over the backside surface 104B of the substrate 104, a trench isolation grid 110G of an isolation material (e.g., 110’ in FIG. 10) having a plurality of trench isolation units 110 vertically extending into the semiconductor substrate 104 from the backside surface 104B of the semiconductor substrate 104 to a first level “L1” that is adjacent to or identical to the frontside surface 104F of the semiconductor substrate 104, and a metallic grid 120G of a metallic material (120’ in FIG. 11) having a plurality of metallic units 120.

In some embodiments, a metallic unit 120 of the plurality of metallic units 120 includes a first portion 120A and a second portion 120B. In some embodiments, the first portion 120A of the metallic unit 120 vertically extends into the trench isolation unit 110 from an upper surface 110F of the trench isolation unit 110 to the first level “L1” and is laterally surrounded by the trench isolation unit 110. In some embodiments, the second portion 120B of the metallic unit 120 vertically overlays the first portion 120A of the metallic unit 120 and protrudes from the upper surface 110F of the trench isolation unit 110 into the first dielectric layer 125 to a second level “L2” that is lower than an upper surface 125F of the first dielectric layer 125.

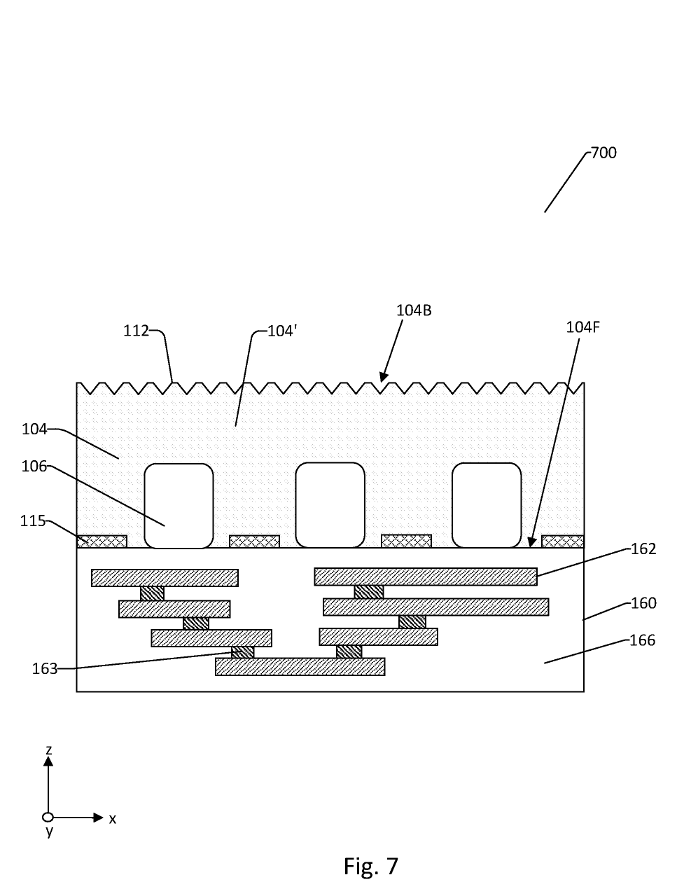

In some embodiments, the trench isolation unit 110 includes a deep trench isolation (DTI) unit, and the isolation material (e.g., 110’ in FIG. 10) of the trench isolation unit 110 includes an oxide material, such as silicon dioxide (SiO₂). In some embodiments, the trench isolation unit 110 is lined with a barrier film 109 of a high-k dielectric material (e.g., 109’ in FIG. 10). The barrier film 109 of the trench isolation unit 110 separates the isolation material (e.g., 110’ in FIG. 10) of the trench isolation unit 110 from a semiconductor material (e.g., 104’ in FIG. 7) of the semiconductor substrate 104. In some embodiments, the semiconductor material (e.g., 104’ in FIG. 7) can be silicon (Si). In some embodiments, the high-k dielectric material (e.g., 109’ in FIG. 10) is selected from aluminum oxide (AlO), hafnium oxide (HfO), titanium oxide (TaO), or zirconium oxide (ZrO).

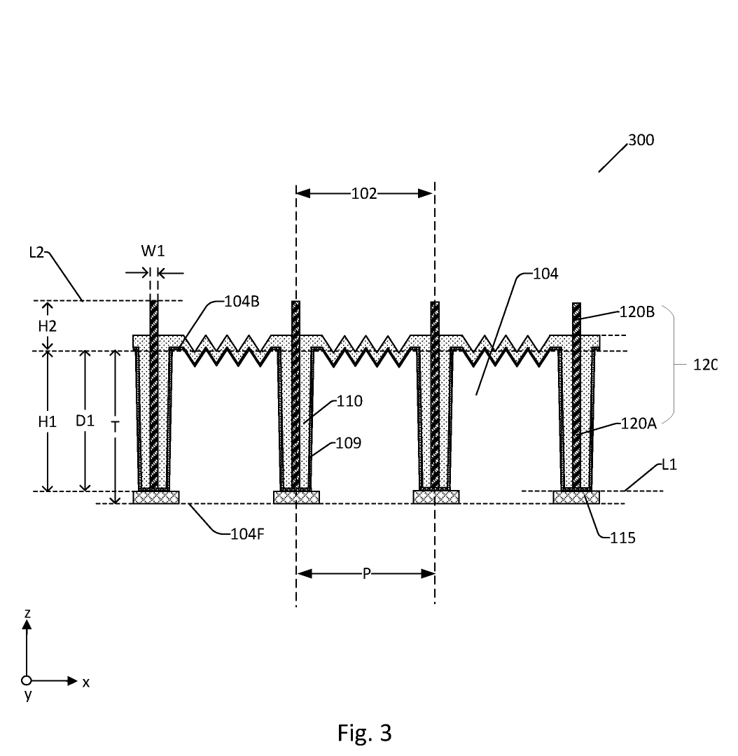

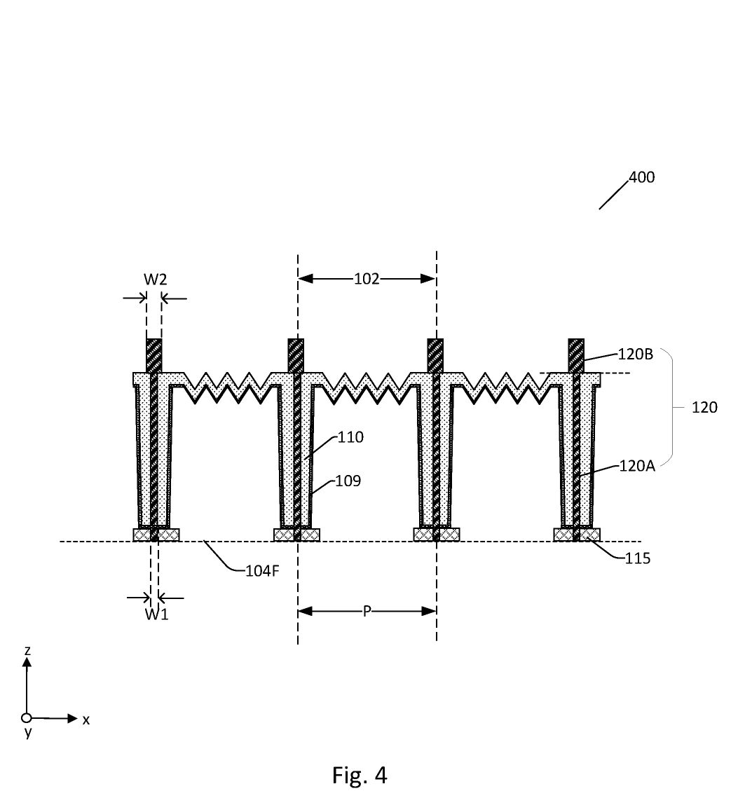

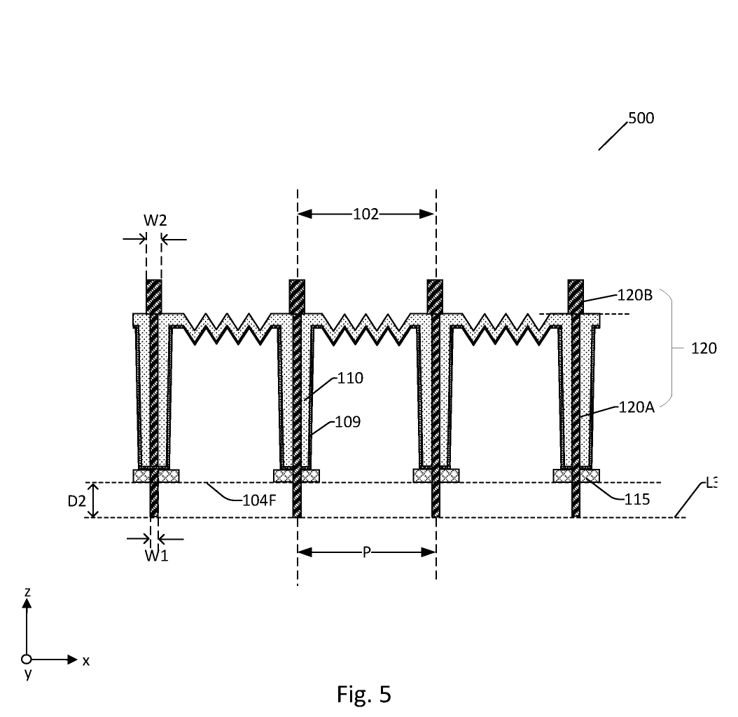

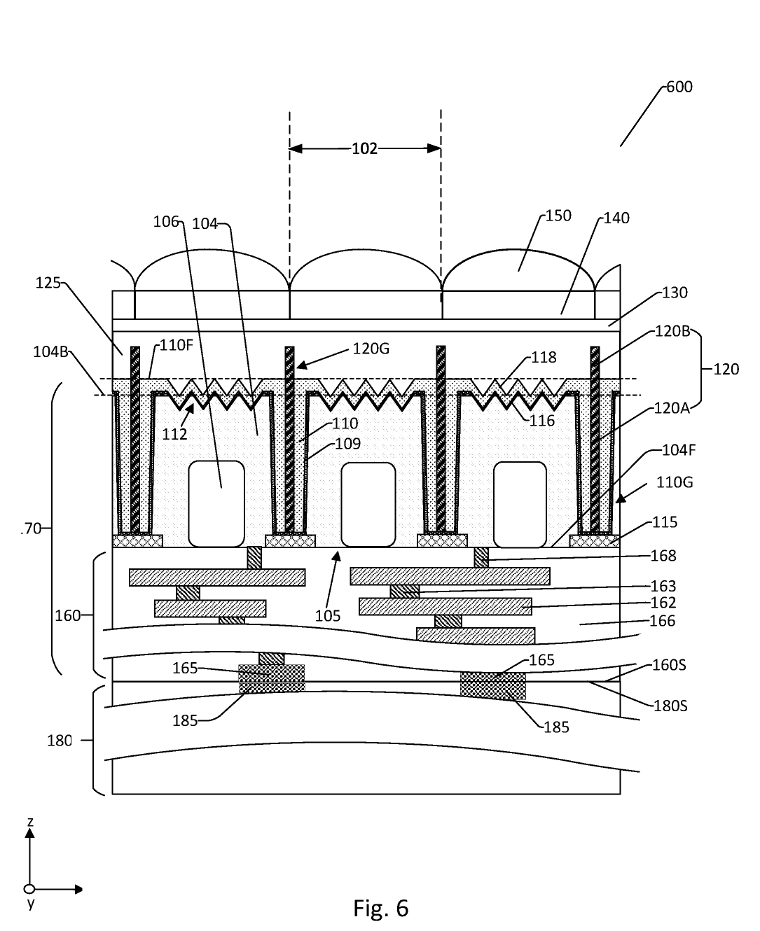

In some embodiments, the metallic material (e.g., 120’ in FIG. 11) of the metallic grid 120G is selected from aluminum (Al), copper (Cu), gold (Au), silver (Ag), tungsten (W), or titanium (Ti). In some embodiments, as shown in FIGS. 1 and 3, the first portion 120A of the metallic unit 120 lands on a shallow trench isolation (STI) structure 115 that is arranged over and adjacent to the frontside surface 104F of the semiconductor substrate 104. In other embodiments, as shown in FIG. 4, the first portion 120A of the metallic unit 120 lands on the frontside surface 104F of the semiconductor substrate 104. In yet other embodiments, as shown in FIG. 5, the first portion 120A of the metallic unit 120 vertically extends through the semiconductor substrate 104 to a third level under the frontside surface 104F of the semiconductor substrate 104, and is in contact with (not shown) an interconnection metal layer (e.g., 162 in FIG. 6) that is arranged under the frontside surface 104F of the semiconductor substrate 104.

In some embodiments, the semiconductor structure 100 for BSI pixel sensors 102 further includes an Anti-Reflection Coating (ARC) layer 130 that is deposited on the upper surface 125F of the first dielectric layer 125 to reduce the reflection of light. In some embodiments, the ARC layer 130 includes silicon dioxide (SiO₂), magnesium fluoride (MgF₂), titanium dioxide (TiO₂), or zinc sulfide (ZnS). By minimizing reflection, the ARC layer 130 advantageously enhances light transmission through the upper surface 125F of the first dielectric layer 125, thereby improving performance and efficiency of the semiconductor structure 100.

In some embodiments, the semiconductor structure 100 for BSI pixel sensors 102 further includes a plurality of color filters (CLs) 140 arranged on an upper surface of the ARC layer 130, and vertically aligned with the plurality of photodiodes 106 arranged under the ARC layer 130. The plurality of color filters 140 are laterally separated from each other. In some embodiments, the the semiconductor structure 100 further includes a plurality of micro lenses (MLs) 150 arranged on and vertically aligned with the plurality of color filters 140. The plurality of micro lenses 150 are laterally separated from each other.

In some embodiments, the semiconductor structure 100 for BSI pixel sensors 102 further includes a high absorption structure 112 that is formed on the backside surface 104B of the semiconductor substrate 104. The high absorption structure 112 can advantageously reduce light reflectance of the backside surface 104B of the semiconductor substrate 104 when the photodiodes 106 are illuminated by light incident upon the backside surface 104B of the semiconductor substrate 104. With the high absorption structure 112, more light is absorbed by the photodiodes 106 in the pixel sensors 102. In some embodiments, the high absorption structure 112 has a saw-toothed profile or other periodic patterns along the backside surface 104B of the semiconductor substrate 104. In some embodiments, the semiconductor substrate 104 has nano-porous silicon and/or some other high absorption semiconductor material at the high absorption structure 112.

In some embodiments, the semiconductor structure 100 for BSI pixel sensors 102 further includes a barrier film 116 arranged on a top surface of the high absorption structure, and an isolation film 118 arranged on a top surface of the barrier film 116. In some embodiments, the barrier film 116 is made of a high-k dielectric material (e.g., 109’ in FIG. 10), which includes aluminum oxide (AlO), hafnium oxide (HfO), titanium oxide (TaO), or zirconium oxide (ZrO). In some embodiments, the isolation film 118 is made of an isolation material (e.g., 110’ in FIG. 10), which includes an oxide material, such as silicon dioxide (SiO₂). In some embodiments, both of the top and bottom surfaces of the barrier film 116 conform to the saw-toothed profile of the high absorption structure 112. In some embodiments, both of the top and bottom surfaces of the isolation film 118 conform to the saw-toothed profile of the high absorption structure 112. In some embodiments, the first dielectric layer 125 overlays the top surface of the isolation film 118.

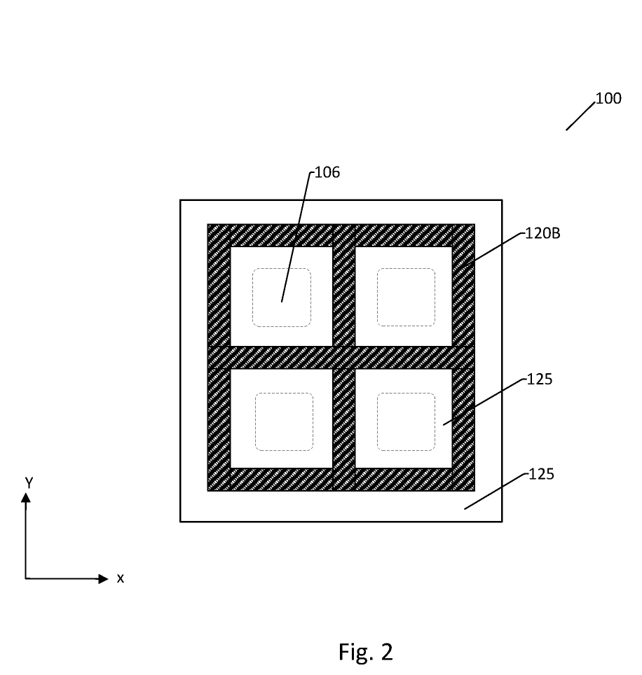

FIG. 2 is a top view of a part of the semiconductor structure 100 for BSI pixel sensors 102 taken along cutline A-A’ in FIG. 1 in accordance with some embodiments. In some embodiments, referring to FIGS. 1 and 2, the first portions 120A and the second potions 120B of the plurality of metallic units 120 define a plurality of regions that laterally surround a plurality of photodiodes 106, respectively.

FIG. 3 is a cross-sectional view 300 illustrating an implementation and some dimensions of a partial semiconductor structure for BSI pixel sensors 102 in accordance with an embodiment. In some embodiments, the first portion 120A of the metallic unit 120 fully extends into the trench isolation unit 110 and lands at the first level “L1” on a shallow trench isolation (STI) structure 115 that is arranged over and adjacent to the frontside surface 104F of the semiconductor substrate 104. As such, the optical performance, such as Modulation Transfer Function (MTF), of the semiconductor structure for BSI pixel sensors 102 can be improved by about 15% compared to an arrangement without metallic unit 120 fully extending into the trench isolation unit 110. In some embodiments, the semiconductor substrate 104 has a thickness “T” from the backside surface 104B to the frontside surface 104F in a range from 2.4 um to 7.2 um. In some embodiments, the trench isolation unit 110 has a depth “D1” in a range from 1.6 um to 7.2 um. In some embodiments, both of the first portion 120A and the second portion 120B of the metallic unit 120 have an identical width W1 in a range from 100 nm to 170 nm. In some embodiments, the first portion 120A has a first height “H1” in a range from 1.6 um to 7.2 um, and the second portion 120B has a second height “H2” in a range from 0.34 um to 0.95 um. In some embodiments, a BSI pixel sensor 102 has a pixel pitch “P” between two adjacent metallic units 120 in a range from 0.28 um to 5.0 um.

FIG. 4 is a cross-sectional view 400 illustrating another implementation and some dimensions of a partial semiconductor structure for BSI pixel sensors 102 in accordance with another embodiment. The implementation as shown in FIG. 4 is similar to the implementation as shown in FIG. 3 except some differences. As shown in FIG. 4, the first portion 120A of the metallic unit 120 fully extends through the trench isolation unit 110 and the shallow trench isolation (STI) structure 115, and lands on the frontside surface 104F of the semiconductor substrate 104. As such, the optical performance, such as Modulation Transfer Function (MTF), of the semiconductor structure for BSI pixel sensors 102 can be improved by about 15% compared to an arrangement without metallic unit 120 fully extending into trench isolation unit 110. In addition, different from the implementation as shown in FIG. 3, the first portion 120A and the second portion 120B of the metallic unit 120 have different widths. In some embodiments, a first width “W1” of the first portion 120A is in a range from 100 nm to 170 nm, and a second width “W2” of the second portion 120A is in a range from 170 nm to 240 nm.

FIG. 5 is a cross-sectional view 500 illustrating another yet implementation and some dimensions of a partial semiconductor structure for BSI pixel sensors 102 in accordance with another yet embodiment. The implementation as shown in FIG. 5 is similar to the implementations as shown in FIGS. 3 and 4 except some differences. As shown in FIG. 5, the first portion 120A of the metallic unit 120 fully extends through the trench isolation unit 110 and the semiconductor substrate 104 to a third level “L3” that is under the frontside surface 104F of the semiconductor substrate 104. In some embodiments, a second depth “D2” from the backside surface 104F to the third level “L3” is in a range from 0.3 um to 0.8 um. In some embodiments, not shown, the first portion 120A of the metallic unit 120 lands on or is in contact with a metallization layer of a plurality of metallization layers 162 within a BEOL metallization stack 160 underlying the semiconductor substrate 104 (in FIG. 6). As such, the optical performance, such as Modulation Transfer Function (MTF), of the semiconductor structure for BSI pixel sensors 102 can be improved by about 20% compared to the arrangement without metallic unit 120 fully extending into trench isolation unit 110.

FIG. 6 is a cross-sectional view of a semiconductor structure for a BSI image sensor package 600 in accordance with some embodiments. In FIG. 6, the BSI image sensor package 600 includes an array (not shown) of pixel sensors 102 arranged in rows and columns on a backside of an integrated circuit 170. In some embodiments, the pixel sensor array includes the pixel sensors 102. In some embodiments, the pixel sensor array can include millions of pixel sensors arranged in hundreds or thousands of rows and hundreds or thousands of columns.

The integrated circuit 170 includes a semiconductor substrate 104, a back-end-of-line (BEOL) metallization stack 160, and a device region 105 located between the semiconductor substrate 104 and the BEOL metallization stack 160. The device region 105 is arranged along the frontside surface 104F of the semiconductor substrate 104, and extends into the semiconductor substrate 104. The device region 105 includes photodiodes 106 corresponding to the pixel sensors 102 and logic devices (not shown), such as transistors, for readout of the photodiodes 106. The photodiodes 106 are arranged in rows and columns within the semiconductor substrate 104, and configured to accumulate charge induced by the photons incident on the photodiodes 106. The photodiodes 106 are optically isolated from each other by a composite grid having a trench isolation grid 110G and a metallic grid 120G, as afore-depicted with reference to FIG. 1, thereby advantageously mitigating the alignment shift problem between the metallic grid and the trench isolation grid and the crosstalk problem among neighboring photodiodes.

The BEOL metallization stack 160 of the integrated circuit 170 underlies the semiconductor substrate 104, and includes a plurality of metallization layers 162 stacked within an interlayer dielectric (ILD) layer 166. One or more vias 163 of the BEOL metallization stack 160 extend between the metallization layers (e.g., 162) to interconnect the metallization layers. Furthermore, one or more contacts 168 of the BEOL metallization stack 160 extend from a metallization layer 162 to the device region 105. The metallization layers 162, the contacts 168, and the vias 163 may be made of a metal material, such as copper or aluminum. The ILD layer 166 may be made of a low-k dielectric (i.e., a dielectric with a dielectric constant less than about 3.9), such as an oxide.

The BEOL metallization stack 160 of the integrated circuit 170 can be bonded to at least one carrier substrate 180. Various suitable bonding techniques (such as wire bonding, through-silicon vias (TSVs), or metal-metal (M-M) and dielectric-dielectric (D-D) bonding) or combinations thereof can be used to bond the BEOL metallization stack 160 of the integrated circuit 170 to at least one carrier substrate 180. In some embodiments, the BEOL metallization stack 160 of the integrated circuit 170 is bonded to at least one carrier substrate 180 by using the hybrid bonding technique, which involves direct bonding of surfaces at the wafer or die level, combining metal-to-metal connections and dielectric-to-dielectric connections.

In some embodiments, as shown in FIG. 6, the BEOL metallization stack 160 of the integrated circuit 170 includes one or more metal connection elements 165 and a dielectric interface 160S, and the carrier substrate 180 includes one or more corresponding metal connection elements 185 and a corresponding dielectric interface 180S, and thus the BEOL metallization stack 160 of the integrated circuit 170 can be bonded to the carrier substrate 180 by hybrid bonding at a wafer level. In this way, the integrated circuit 170 including the BEOL metallization stack 160 can be bonded to many (such as two to four) carrier wafers (such as 180 in FIG. 6), thereby advantageously allowing for high-density integration.

FIGS. 7-17 are cross-sectional views of intermediate semiconductor structures that show some example steps of a method for fabricating a semiconductor structure for BSI pixel sensors 102 in accordance with some embodiments. Although FIGS. 7-17 are described in relation to a method, it will be appreciated that the structures disclosed in FIGS. 7-17 are not limited to such a method, but instead may stand alone as structures independent of the method.

Referring to cross-sectional view 700 of FIG. 7, a semiconductor substrate 104 with embedded photodiodes 106 for a semiconductor device is provided. A plurality of shallow trench isolation (STI) structures 115 extend into the substrate 104 from the frontside surface 104F of the semiconductor substrate 104, are substantially surrounded by the semiconductor substrate 104, and laterally define boundaries for the to-be-formed BSI pixel sensors 102 (e.g., in FIGS. 1 and 6). In some embodiments, the semiconductor substrate 104 is made of a semiconductor material 104’ (such as silicon), has a frontside surface 104F and a backside surface 104B, and includes a high absorption structure 112 that is formed on the backside surface 104B thereof and has a saw-toothed profile along the backside surface 104B thereof. In some embodiments, the semiconductor device also includes a back-end-of-line (BEOL) metallization stack 160, which underlies the substrate 104, and includes a plurality of metallization layers 162 stacked within an interlayer dielectric (ILD) layer 166, and a plurality of vias 163 extending between the plurality of metallization layers 162 to interconnect them.

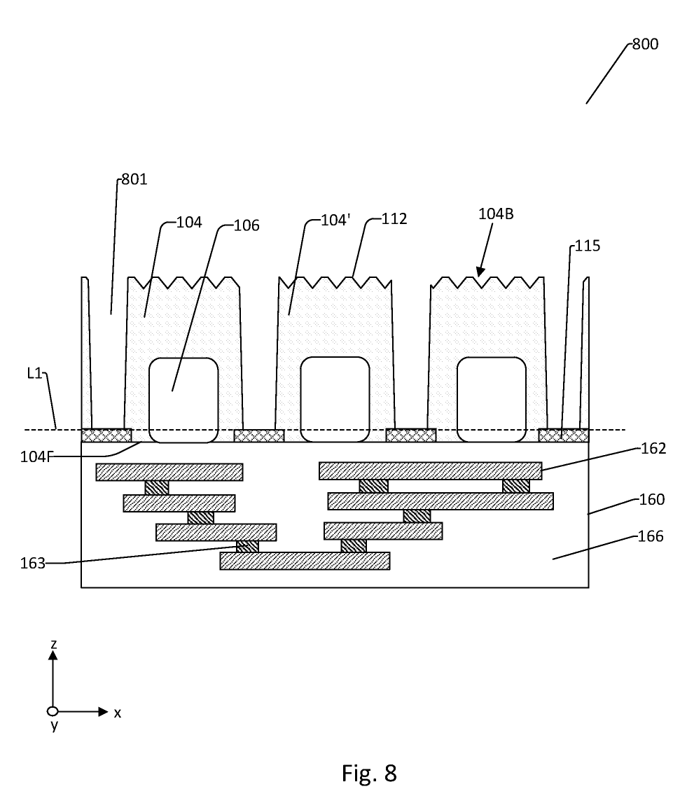

Next, referring to cross-sectional view 800 of FIG. 8, a plurality of trenches 801 are formed that vertically extends into the semiconductor substrate 104 from a backside surface 104B of the semiconductor substrate 104 to a first level “L1” that is above and adjacent to the frontside surface 104F of the semiconductor substrate 104. In some embodiments, photolithography and etching processes can be employed to form the plurality of trenches 801. The plurality of trenches 801 laterally surround the plurality of photodiodes 106 when viewed in a top-down direction.

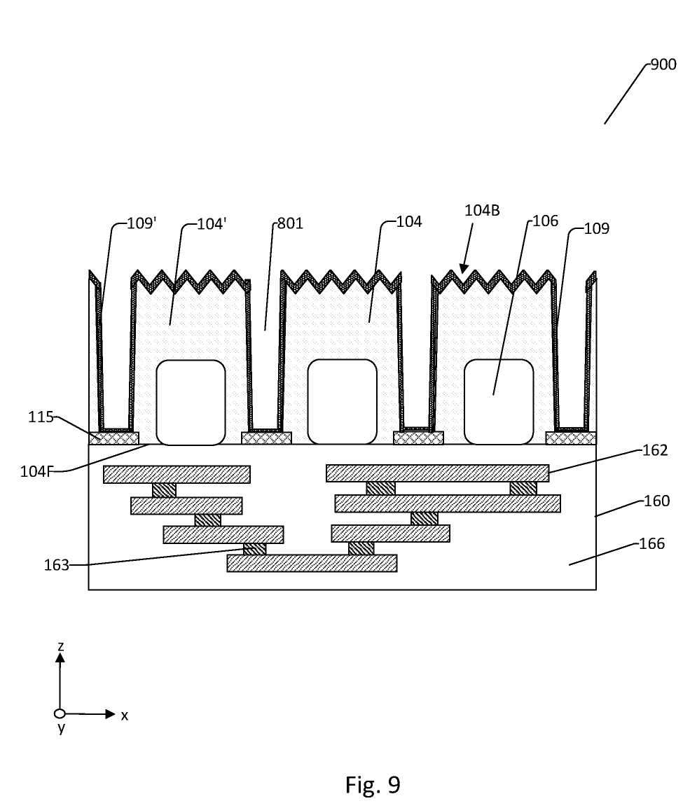

Next, referring to cross-sectional view 900 of FIG. 9, a plurality of barrier films 109 of a high-k dielectric material 109’ are formed on inner surfaces of the plurality of trenches 801 and on the remaining backside surface 104B of the semiconductor substrate 104. In some embodiments, a deposition process, such as an atomic layer deposition (ALD), is used to form the plurality of barrier films 109. The high-k dielectric material 109’ can be aluminum oxide (AlO), hafnium oxide (HfO), titanium oxide (TaO), or zirconium oxide (ZrO).

Next, referring to cross-sectional view 1000 of FIG. 10, a plurality of trench isolation units 110 made of an isolation material 110’ are deposited over the plurality of barrier films 109 made of the high-k dielectric material 109’. In addition, the isolation material 110’ is also deposited over the remaining backside surface 104B of the semiconductor substrate 104. In some embodiments, a deposition process, such as Chemical Vapor Deposition (CVD) or Physical Vapor Deposition (PVD), is used to form the plurality of barrier films 109. The isolation material 110’ can be an oxide material, such as silicon dioxide (SiO₂).

Next, referring to cross-sectional view 1100 of FIG. 11, a metallic material 120’ is deposited that fills into the plurality of trenches 801 (e.g., in FIG. 10) and covers the isolation material 110’ deposited on the remaining backside surface 104B of the semiconductor substrate 104. The first portions 120A (e.g., in FIGS. 1 and 6) of a plurality of metallic units 120 are formed by the metallic material 120’ filled into the plurality of trenches 801. In some embodiments, an atomic layer deposition (ALD) process is first performed for a barrier film of a barrier material (such as TiN and TaN) in the plurality of trenches 801, and a Chemical Vapor Deposition (CVD) process is subsequently performed to deposit the metallic material 120’. The metallic material 120’ can be aluminum (Al), copper (Cu), gold (Au), silver (Ag), tungsten (W), or titanium (Ti), or a combination thereof.

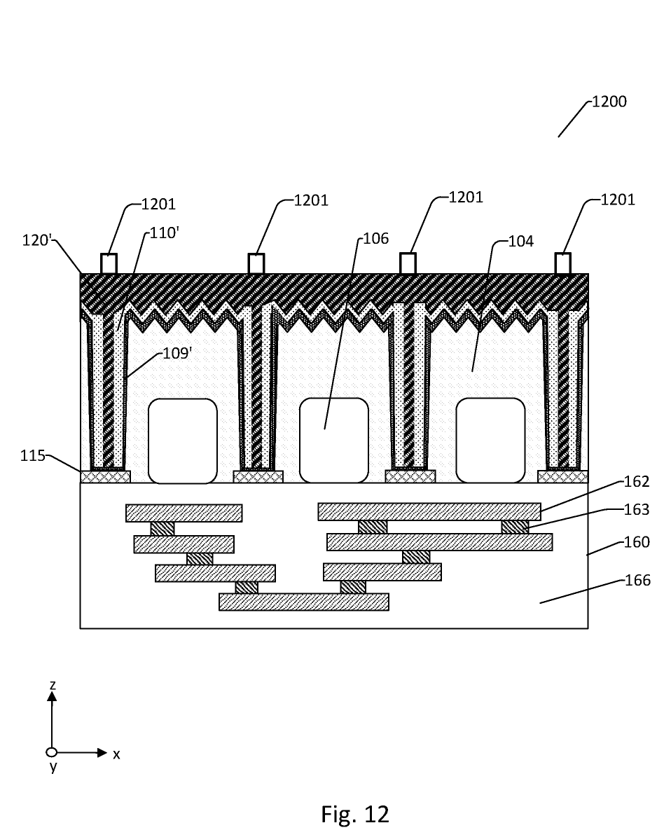

Next, referring to cross-sectional view 1200 of FIG. 12, a mask layer with patterns 1201 is formed over the metallic material 120’ that overlays the isolation material 110’ filled into the plurality of trenches 801 and covers the isolation material 110’ deposited on the remaining backside surface 104B of the substrate 104. In some embodiments, photolithography and etching processes can be employed to form the patterns 1201 of the mask layer.

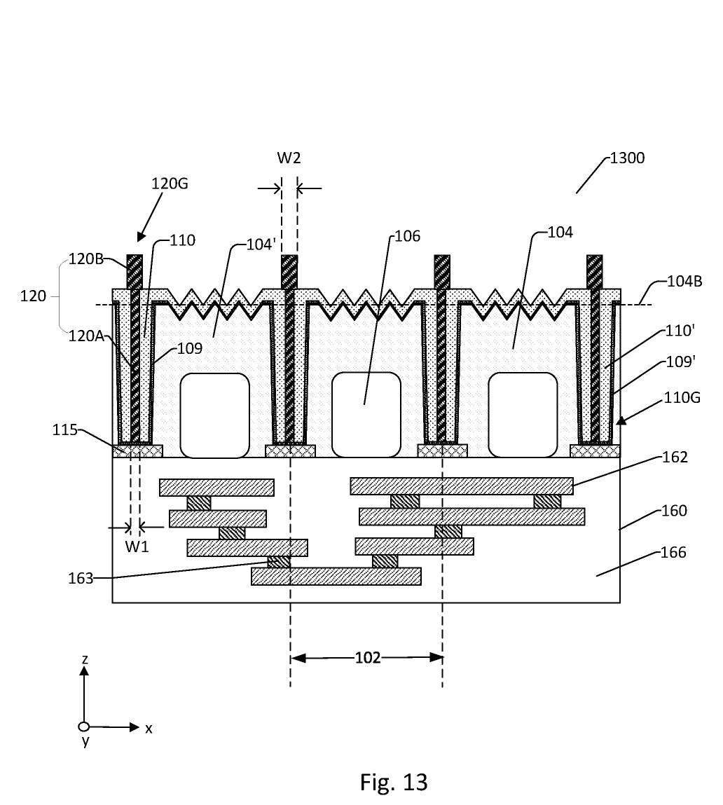

Next, referring to cross-sectional view 1300 of FIG. 13, the second portions 120B of the plurality of metallic units 120 overlaying the first portions 120A of the plurality of metallic units 120 are formed. In some embodiments, the second portions 120B of the plurality of metallic units 120 are formed by removing excessive portions of the metallic material 120’ covering the isolation material 110’ deposited on the remaining backside surface 104B of the substrate 104 to expose the isolation material 110’ deposited on the remaining backside surface 104B of the substrate 104, while retaining remaining portions of the metallic material 120’ overlaying the first portions 120A of the plurality of metallic units 120. In some embodiments, the excessive portions of the metallic material 120’ are removed by etching through the mask layer overlaying the metallic material 120’ covering the isolation material 110’ deposited on the remaining backside surface 104B of the substrate 104 according to the patterns 1201 in the mask layer (in FIG. 12), and stopping at an upper surface of the isolation material 110’ deposited on the remaining backside surface 104B of the substrate 104.

In some embodiments, referring to FIGS. 4 and 13, a first width “W1” of the first portion 120A is in a range from 100 nm to 170 nm, and a second width “W2” of the second portion 120A is in a range from 170 nm to 240 nm. In other embodiments, referring to FIG. 3, the first portion 120A and the second portion 120B has an identical width that is in a range from 100 nm to 170 nm.

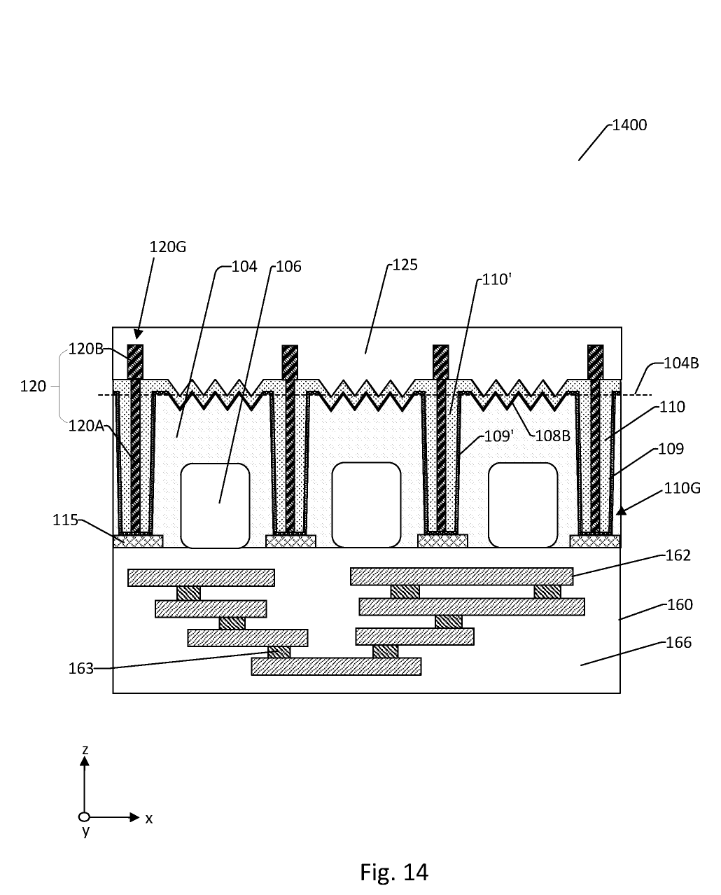

Next, referring to cross-sectional view 1400 of FIG. 14, a first dielectric layer 125 is deposited over the second portions 120B of the plurality of metallic units 120 and over the exposed upper surface of the isolation material 110’ deposited on the remaining backside surface 104B of the semiconductor substrate 104. The first dielectric layer 125 can be made of a dielectric material, such as silicon oxide (SiO₂). The plurality of trench isolation units 110 collectively create a trench isolation grid 110G, the plurality of metallic units 120 fully extend into the plurality of trench isolation units 110 and collectively create a metallic grid 120G, and the trench isolation grid 110G and the metallic grid 120G combinedly create a composite metallic grid, thereby advantageously mitigating the alignment shift problem between the metallic grid 120G and the trench isolation grid 110G, and the crosstalk problem among neighboring photodiodes 106.

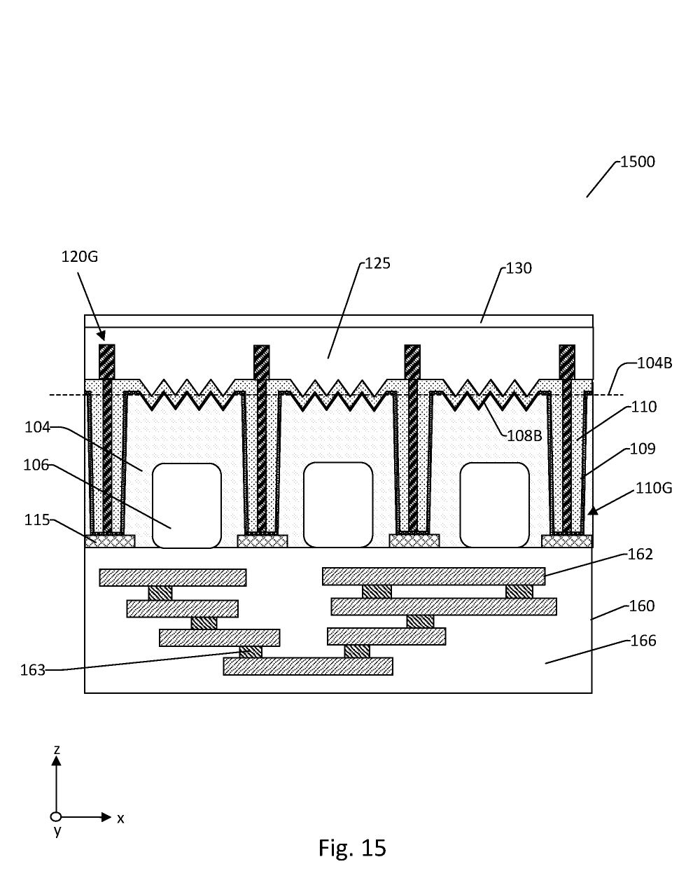

Next, referring to cross-sectional view 1500 of FIG. 15, an Anti-Reflection Coating (ARC) layer 130 is formed on the upper surface of the first dielectric layer 125 by a deposition process (such as a CVD process), thereby reducing the reflection of light from the BSI pixel sensor 102 of the semiconductor device and improving performance and efficiency of the semiconductor device. In some embodiments, the ARC layer 130 is made of a material, such as silicon dioxide (SiO₂), magnesium fluoride (MgF₂), titanium dioxide (TiO₂), or zinc sulfide (ZnS), or a combination thereof.

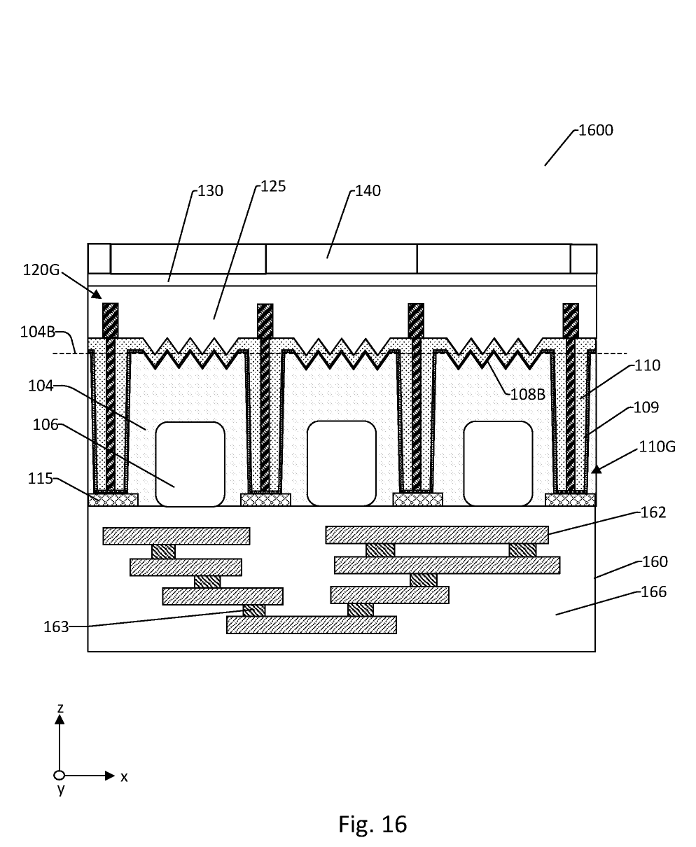

Next, referring to cross-sectional view 1600 of FIG. 16, a plurality of color filters (CLs) 140 are formed on an upper surface of the ARC layer 130. The plurality of color filters 140 are vertically aligned with the plurality of photodiodes 106 arranged under the ARC layer 130. The plurality of color filters 140 are laterally separated from each other.

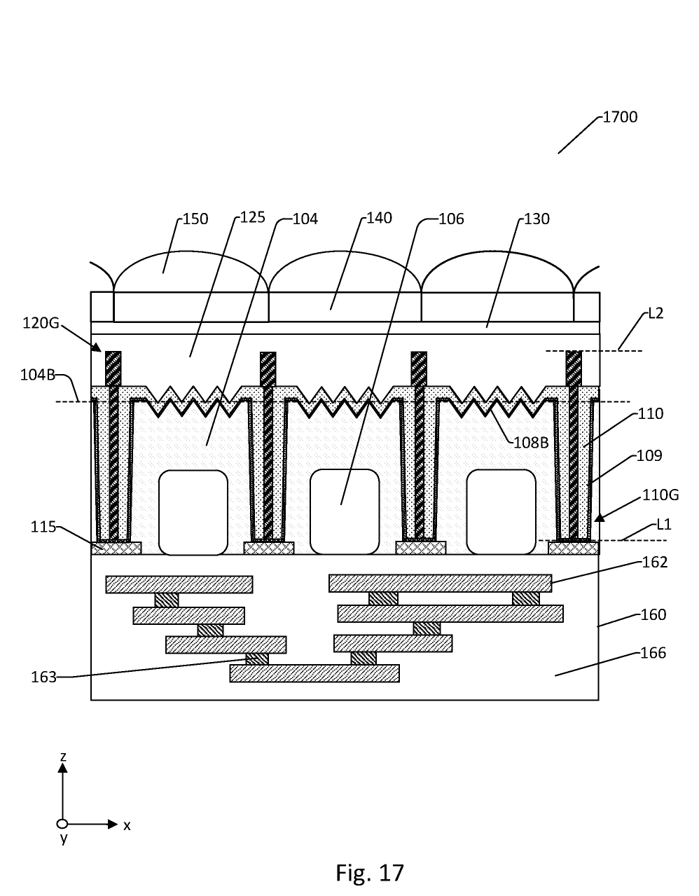

Next, referring to cross-sectional view 1700 of FIG. 17, a plurality of micro lenses (MLs) 150 are formed on the plurality of color filters 140 and vertically aligned with the plurality of color filters 140. The plurality of micro lenses 150 are laterally separated from each other.

As such, a semiconductor structure for BSI pixel sensors 102 with the metallic grid 120G fully embedded within the trench isolation grid 110G is formed, in which the trench isolation grid 110G and the metallic grid 120G combinedly create a composite metallic grid, thereby advantageously mitigating the alignment shift problem between the metallic grid and the trench isolation grid and the crosstalk problem among neighboring photodiodes.

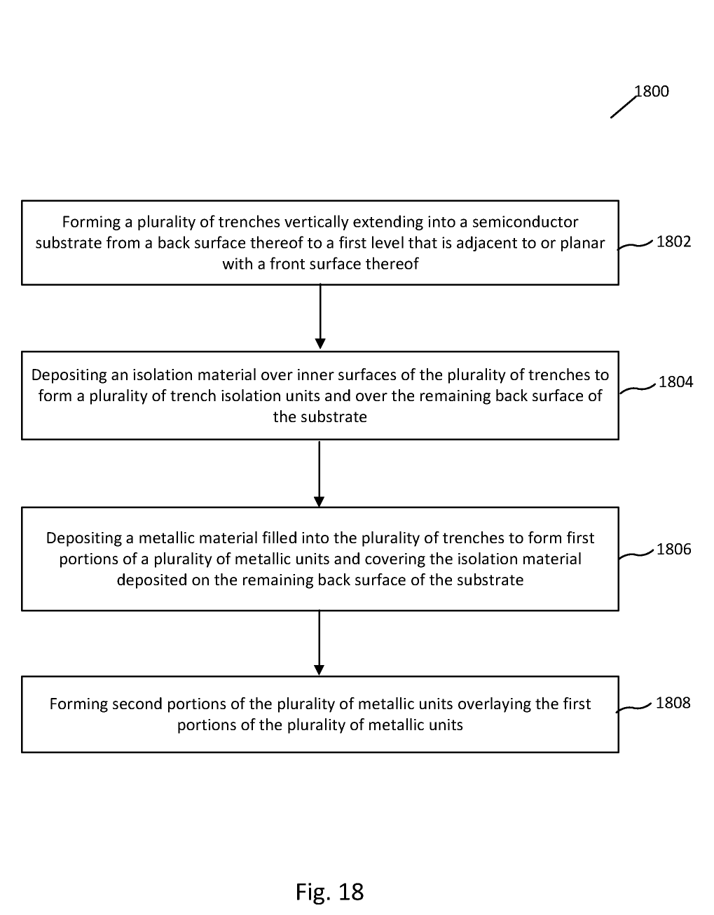

FIG. 18 is a flow chart showing processes implemented in a method 1800 of fabricating the semiconductor structure 100 for BSI pixel sensors 102 as shown in FIG. 1 in accordance with some embodiments. While the method 1800 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

In some embodiments, the semiconductor structure 100 for BSI pixel sensors 102 in FIG. 1 fabricated by the method 1800 in FIG. 18 includes: a semiconductor substrate 104 having a plurality of photodiodes 106 formed therein; a trench isolation grid 110G of an isolation material 110’ having a plurality of trench isolation units 110 vertically extending into the semiconductor substrate 104 from the backside surface 104B thereof to a first level “L1” identical to or adjacent to a frontside surface 104F thereof, in which a trench isolation unit 110 of the plurality of trench isolation units laterally surrounds a photodiode 106 of the plurality of photodiodes 106; and a metallic grid 120G of a metallic material 120’ having a plurality of metallic units 120. A metallic unit 120 of the plurality of metallic units 120 includes a first portion 120A vertically extending into the trench isolation unit 110 from an upper surface 110F thereof to the first level “L1” and laterally surrounded by the trench isolation unit 110, and a second portion 120B vertically overlaying the first portion 120A and protruding from the upper surface of the trench isolation unit 110 into a first dielectric layer 125 arranged over a backside surface 104B of the semiconductor substrate 104 to a second level “L2” lower than an upper surface of the first dielectric layer 125.

Referring to FIGS. 7-8 and 18, the method 1800 starts with operation 1802 of forming a plurality of trenches 801 that vertically extend into a semiconductor substrate 104 from a backside surface 104B thereof to a first level “L1” that is adjacent to or planar with a frontside surface 104F thereof. The substrate 104 has a plurality of photodiodes 106 formed therein.

Next, referring to FIGS. 9-10 and 18, the method 1800 proceeds to operation 1804 of depositing an isolation material 110’ over inner surfaces of the plurality of trenches 801 to form a plurality of trench isolation units 110 and over the remaining backside surface 104B of the semiconductor substrate 104. The isolation material 110’ can be an oxide material such as silicon dioxide (SiO₂). In some embodiments, as shown in FIG. 9, a barrier film 109 of a high-k dielectric material 109’ is deposited on the inner surfaces of the plurality of trenches 801 and on the remaining backside surface 104B of the semiconductor substrate 104, before depositing the isolation material 110’ in FIG. 10 over inner surfaces of the plurality of trenches 801 and over the remaining backside surface 104B of the semiconductor substrate 104. The high-k dielectric material 109’ can be aluminum oxide (AlO), hafnium oxide (HfO), titanium oxide (TaO), or zirconium oxide (ZrO).

Next, referring to FIGS. 11 and 18, the method 1800 proceeds to operation 1806 of depositing a metallic material 120’ that is filled into the plurality of trenches 801 to form the first portions 120A of the plurality of metallic units 120 and covers the isolation material 110’ deposited on the remaining backside surface 104B of the semiconductor substrate 104. The metallic material 120’ can be aluminum (Al), copper (Cu), gold (Au), silver (Ag), tungsten (W), or titanium (Ti).

Next, referring to FIGS. 12-13 and 18, the method 1800 proceeds to operation 1808 of forming the second portions 120B of the plurality of metallic units 120 that overlay the first portions 120A of the plurality of metallic units 120. Referring to FIG. 12, a mask layer with patterns 1201 is formed over the metallic material 120’ covering the isolation material 110’ deposited on the remaining backside surface 104B of the semiconductor substrate 104. Referring to FIG. 13, the second portions 120B of the plurality of metallic units 120 overlaying the first portions 120A of the plurality of metallic units 120 are formed by removing excessive portions of the metallic material 120’ covering the isolation material 110’ deposited on the remaining backside surface 104B of the semiconductor substrate 104 to expose the isolation material 110’ deposited on the remaining backside surface 104B of the semiconductor substrate 104, while retaining remaining portions of the metallic material 120’ overlaying the first portions 120A of the plurality of metallic units 120.

As such, the plurality of trench isolation units 110 collectively create a trench isolation grid 110G, the plurality of metallic units 120 fully extend into the plurality of trench isolation units 110 and collectively create a metallic grid 120G, and the trench isolation grid 110G and the metallic grid 120G combinedly create a composite metallic grid.

Therefore, the present disclosure relates to a new semiconductor structure for BSI image sensors including the composite metallic grid and a new method of manufacturing the same, thereby advantageously mitigating the alignment shift problem between the metallic grid and the trench isolation grid and the crosstalk problem among neighboring photodiodes, and thus advantageously improving optical performance such as Modulation Transfer Function (MTF) of the BSI image sensors.

Accordingly, in some embodiments, the present disclosure relates to a semiconductor device including: a semiconductor substrate including a plurality of photodiodes formed therein, wherein a first dielectric layer is arranged over a backside surface of the substrate; a trench isolation grid of an isolation material including a plurality of trench isolation units vertically extending into the substrate from the backside surface thereof to a first level identical to or adjacent to a frontside surface thereof, wherein a trench isolation unit of the plurality of trench isolation units laterally surrounds a photodiode of the plurality of photodiodes; and a metallic grid of a metallic material including a plurality of metallic units, wherein a metallic unit of the plurality of metallic units includes: a first portion vertically extending into the trench isolation unit from an upper surface thereof to the first level and laterally surrounded by the trench isolation unit, and a second portion vertically overlaying the first portion and protruding from the upper surface of the trench isolation unit into the first dielectric layer to a second level lower than an upper surface of the first dielectric layer.

In other embodiments, the present disclosure relates to a method including: forming a plurality of trenches vertically extending into a semiconductor substrate from a backside surface thereof to a first level that is adjacent to or planar with a frontside surface thereof, wherein the substrate has a plurality of photodiodes formed therein; depositing an isolation material over inner surfaces of the plurality of trenches to form a plurality of trench isolation units and over the remaining backside surface of the substrate; depositing a metallic material filled into the plurality of trenches to form first portions of a plurality of metallic units and covering the isolation material deposited on the remaining backside surface of the substrate; and forming second portions of the plurality of metallic units overlaying the first portions of the plurality of metallic units.

In yet other embodiments, the present disclosure relates to a method including: providing a semiconductor substrate having a plurality of photodiodes formed therein; forming a trench isolation grid including an isolation material, wherein forming the trench isolation grid includes forming a plurality of trench isolation units vertically extending from the backside surface into the substrate to a first level identical to or adjacent to a frontside surface of the substrate, wherein a trench isolation unit of the plurality of trench isolation units laterally surrounds a photodiode of the plurality of photodiodes; and forming a metallic grid including a metallic material and a plurality of metallic units, wherein forming a metallic unit of the plurality of metallic units includes: forming a first portion vertically extending into the trench isolation unit from an upper surface of the trench isolation unit to the first level and laterally surrounded by the trench isolation unit, and forming a second portion vertically overlaying the first portion and protruding from the upper surface of the trench isolation unit into the first dielectric layer to a second level lower than an upper surface of the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a plurality of photodiodes formed therein, wherein a first dielectric layer is arranged over a backside surface of the substrate;
a trench isolation grid of an isolation material comprising a plurality of trench isolation units vertically extending into the substrate from the backside surface thereof to a first level adjacent to or identical to a frontside surface thereof, wherein a trench isolation unit of the plurality of trench isolation units laterally surrounds a photodiode of the plurality of photodiodes; and
a metallic grid of a metallic material comprising a plurality of metallic units, wherein a metallic unit of the plurality of metallic units comprises:
a first portion vertically extending into the trench isolation unit from an upper surface thereof to the first level and laterally surrounded by the trench isolation unit, and
a second portion vertically overlaying the first portion and protruding from the upper surface of the trench isolation unit into the first dielectric layer to a second level below an upper surface of the first dielectric layer.

2. The semiconductor device of claim 1, wherein the trench isolation unit includes a deep trench isolation (DTI) unit, and wherein the isolation material of the trench isolation unit comprises an oxide material.

3. The semiconductor device of claim 1, wherein the trench isolation unit is lined with a barrier film of a high-k dielectric material, and wherein the high-k dielectric material comprises aluminum oxide (AlO), hafnium oxide (HfO), titanium oxide (TaO), or zirconium oxide (ZrO).

4. The semiconductor device of claim 1, wherein the first portion of the metallic unit lands on a shallow trench isolation (STI) structure arranged over and adjacent to the frontside surface of the substrate.

5. The semiconductor device of claim 1, wherein the first portion of the metallic unit lands on the frontside surface of the substrate.

6. The semiconductor device of claim 1, wherein the first portion of the metallic unit vertically extends through the substrate to a third level under the frontside surface of the substrate and is in contact with an interconnection metal layer of a plurality of interconnection metal layers arranged under the frontside surface of the substrate.

7. The semiconductor device of claim 1, wherein the metallic material is aluminum (Al), copper (Cu), gold (Au), silver (Ag), tungsten (W), or titanium (Ti).

8. The semiconductor device of claim 1, further comprising:
a high absorption structure arranged in parts of the backside surface of the substrate and having a saw-toothed profile;
a barrier film of a high-k dielectric material arranged on a top surface of the high absorption structure; and
an isolation film of the isolation material arranged on a top surface of the barrier film.

9. The semiconductor device of claim 8, wherein the first dielectric layer overlays a top surface of the isolation film.

10. The semiconductor device of claim 9, wherein the top surface and a bottom surface of the barrier film both conform to the saw-toothed profile, and wherein the top surface and a bottom surface of the isolation film both conform to the saw-toothed profile.

11. A method, comprising:
forming a plurality of trenches vertically extending into a substrate from a backside surface thereof to a first level that is adjacent to or planar with a frontside surface thereof, wherein the substrate has a plurality of photodiodes formed therein;
depositing an isolation material over inner surfaces of the plurality of trenches to form a plurality of trench isolation units and over the remaining backside surface of the substrate;
depositing a metallic material filled into the plurality of trenches to form first portions of a plurality of metallic units and covering the isolation material deposited on the remaining backside surface of the substrate; and
forming second portions of the plurality of metallic units overlaying the first portions of the plurality of metallic units.

12. The method of claim 11, wherein forming the second portions of the plurality of metallic units comprises:
removing excessive portions of the metallic material covering the isolation material deposited on the remaining backside surface of the substrate to expose the isolation material deposited on the remaining backside surface of the substrate, while retaining remaining portions of the metallic material overlaying the first portions of the plurality of metallic units.

13. The method of claim 12, wherein removing the excessive portions of the metallic material comprises:
forming a mask layer with patterns over the metallic material covering the isolation material deposited on the remaining backside surface of the substrate; and
etching through the mask layer according to the patterns and stopping at an upper surface of the isolation material deposited on the remaining backside surface of the substrate.

14. The method of claim 12, further comprising:
depositing a first dielectric layer over the second portions of the plurality of metallic units and over the exposed isolation material deposited on the remaining backside surface of the substrate.

15. The method of claim 11, wherein the plurality of trench isolation units collectively create a trench isolation grid, and wherein the first portions and the second portions of the plurality of metallic units collectively create a metallic grid.

16. The method of claim 11, further comprising forming barrier films of a high-k dielectric material on the inner surfaces of the plurality of trenches and on the remaining backside surface of the substrate, before depositing the isolation material over inner surfaces of the plurality of trenches to form a plurality of trench isolation units and over the remaining backside surface of the substrate.

17. The method of claim 11, wherein forming the plurality of trenches comprises:
forming a mask layer with patterns over the backside surface of the substrate; and
etching through the mask layer and into the substrate according to the patterns.

18. A method, comprising:
providing a semiconductor substrate having a plurality of photodiodes formed therein;
forming a trench isolation grid comprising an isolation material, wherein forming the trench isolation grid comprises forming a plurality of trench isolation units vertically extending from a backside surface into the substrate to a first level identical to or adjacent to a frontside surface of the substrate, wherein a trench isolation unit of the plurality of trench isolation units laterally surrounds a photodiode of the plurality of photodiodes; and
forming a metallic grid comprising a metallic material and a plurality of metallic units, wherein forming a metallic unit of the plurality of metallic units comprises:
forming a first portion vertically extending into the trench isolation unit from an upper surface of the trench isolation unit to the first level and laterally surrounded by the trench isolation unit, and
forming a second portion vertically overlaying the first portion and protruding from the upper surface of the trench isolation unit into a first dielectric layer to a second level below an upper surface of the first dielectric layer.

19. The method of claim 17, further comprising forming a first dielectric layer arranged over the backside surface of the substrate to cover at least the second portion of the metallic unit, wherein the second portion of the metallic unit vertically protrudes from an upper surface of the trench isolation unit into the first dielectric layer to a second level below an upper surface of the first dielectric layer.

20. The method of claim 19, further comprising:
forming a high absorption structure in the backside surface of the substrate before forming the first dielectric layer, wherein the first dielectric layer is deposited over the high absorption structure.
